(19) United States
(12) Patent Application Publication
(10) Pub. No.: US 2008/0020303 A1
(43) Pub. Date: Jan. 24, 2008

(54) Alignment for contact lithography

(76) Inventors: Wei Wu, Palo Alto, CA (US); Shih-Yuan Wang, Palo Alto, CA (US); Richard Stanley Williams, Palo Alto, CA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/492,502

(22) Filed: Jul. 24, 2006

(51) Int. Cl. G03F 9/00

(52) U.S. Cl. 430/22; 355/78

(57) ABSTRACT

A contact lithography system includes a patterning tool having a pattern for transfer to a substrate; and at least one alignment device coupled to the patterning tool. The alignment device is configured to measure alignment between the patterning tool and a substrate for receiving the pattern of the patterning tool. A contact lithography method includes aligning a patterning tool having a pattern for transfer with a substrate for receiving the pattern of the patterning tool using at least one alignment device coupled to the patterning tool.

### BACKGROUND

Contact lithography involves direct contact between a patterning tool (e.g., a mask, mold, template, etc.) and a substrate on which micro-scale and/or nano-scale structures are to be fabricated. Photographic contact lithography and imprint lithography are two examples of contact lithography methodologies. In photographic contact lithography, the patterning tool (i.e., the mask) is aligned with and then brought into contact with the substrate or with a pattern-receiving layer of the substrate. Some form of light or radiation is then used to expose those portions of the substrate that are not covered by the mask so as to transfer the pattern of the mask to the pattern-receiving layer of the substrate. Similarly, in imprint lithography, the patterning tool (i.e., the mold) is aligned with the substrate after which the mold is pressed into the substrate such that the pattern of the mold is imprinted on, or impressed into, a receiving surface of the substrate.

With either method, alignment between the patterning tool and the substrate is very important. The method for aligning the patterning tool and substrate generally involves holding the patterning tool a small distance above the substrate while relative lateral and rotational adjustments (e.g., x-y translation and/or angular rotation adjustments) are made. Either the patterning tool or the substrate, or both, may be moved during the process of alignment. The patterning tool is then brought into contact with the substrate to perform the lithographic patterning.

With these traditional lithography techniques, there may be some vibration of the patterning tool and/or substrate during the alignment process. Unfortunately, such vibration can significantly degrade the accuracy of the resulting alignment and pattern transfer. Previous systems have consequently tried expensive mechanical measures to control vibration during alignment.

With certain contact or imprint lithography techniques, the patterning tool and substrate vibrate together, thereby minimizing any alignment error caused by vibration. This is because any displacement caused by vibrations is experienced simultaneously and equally by both the patterning tool and the substrate. However, vibrations also affect systems that are used to measure or verify the alignment between the patterning tool and the substrate. Additionally, the vibrations experienced by alignment measuring systems are generally not consistent with the vibrations experienced by the patterning tool and substrate being measured.

Since alignment equipment often experiences vibrations substantially different from those of the patterning tool and substrate, it becomes difficult to accurately measure and adjust alignment. For example, a microscope for detecting the alignment of a patterning tool and substrate experiences vibrations different from those experienced by the patterning tool and substrate. The differential vibrations blur the image captured by the microscope and consequently decrease the sensitivity of alignment measurements making it difficult to ensure accurate alignment between the patterning tool and substrate.

### SUMMARY

A contact lithography system includes a patterning tool having a pattern for transfer to a substrate; and at least one alignment device coupled to the patterning tool. The alignment device is configured to measure alignment between the patterning tool and a substrate for receiving the pattern of the patterning tool. A contact lithography method includes aligning a patterning tool having a pattern for transfer with a substrate for receiving the pattern of the patterning tool using at least one alignment device coupled to the patterning tool.

### BRIEF DESCRIPTION OF THE DRAWINGS

The accompanying drawings illustrate various embodiments of the principles being described in this specification and are a part of the specification. The illustrated embodiments are merely examples and do not limit the scope of the principles described herein.

FIG. 1 is a schematic side view of a contact lithography apparatus incorporating an alignment device in a mask, according to one exemplary embodiment.

FIG. 2 is a schematic side view of a contact lithography apparatus employing an optical alignment device coupled to a mask, according to one exemplary embodiment.

FIG. 3A is a schematic side view of a contact lithography apparatus employing an optical sensor coupled to a mask, according to one exemplary embodiment. FIG. 3B is a block diagram representing a system for gathering and processing alignment data, according to one exemplary embodiment.

FIG. 4 is a flowchart illustrating a process of aligning and patterning a substrate with a mask, according to one exemplary embodiment.

Throughout the drawings, identical reference numbers designate similar, but not necessarily identical, elements.

### DETAILED DESCRIPTION

The present specification describes exemplary methods and systems that facilitate alignment of a patterning tool and a substrate for contact lithography. To improve the accuracy, precision, and vibration tolerance of the alignment between the patterning tool and substrate, optics and/or sensors are integrated into the patterning tool.

In various embodiments, one or more spacers are employed between the patterning tool and the substrate to establish a parallel and proximal alignment therebetween. The parallel and proximal alignment provided by the spacers is readily maintained during lateral and/or rotational adjustments between the patterning tool and the substrate to establish a complete, desired alignment of the tool and the substrate. In other embodiments, the patterning tool and substrate may be mechanically coupled without using a spacer. Rather, the tool and substrate may be in direct contact and so mechanically coupled or coupled through a shorter mechanical path by a member other than a spacer.

In some embodiments, the optics, sensors, patterning tools, the spacers, and the substrate may react to vibration essentially as a single unit, thus reducing, and in some instances minimizing, differential vibration-induced alignment errors that are present in conventional contact lithography systems. According to some embodiments, the parallel and proximal alignment using spacers may reduce problems of alignment and stability related to vibration in contact lithography, while the integrated optics and/or sensors improve the measurability of the alignment between the patterning tool and the substrate.

As used herein and in the appended claims, the term “deformation” refers to both a plastic deformation and an elastic deformation. As used herein, “plastic deformation” means an essentially non-reversible, non-recoverable, permanent change in shape in response to an applied force. For example, a “plastic deformation” includes a deformation resulting from a brittle fracture of a material under normal stress (e.g., a cracking or shattering of glass) as well as plastic deformations that occur during shear stress (e.g., bending of steel or molding of clay). Also, as used herein, “elastic deformation” means a change in shape in response to an applied force where the change in shape is essentially temporary and/or generally reversible upon removal of the force. The term “flexure” is considered herein to have the same meaning as “deformation,” and the terms are used interchangeably, as are “flex” and “deform,” “flexible” and “deformable,” and “flexing” and “deforming,” or the like.

As used herein and in the appended claims, the term “deformation” further generally includes within its scope one or both of a passive deformation and an active deformation. Herein, “passive deformation” refers to deformation that is directly responsive to an applied deforming force or pressure. For example, essentially any material that can be made to act in a spring-like manner either by virtue of a material characteristic and/or a physical configuration or shape may be passively deformable. As used herein, the term “active deformation” refers to any deformation that may be activated or initiated in a manner other than by simply applying a deforming force. For example, a lattice of a piezoelectric material undergoes active deformation upon application of an electric field thereto independent of any applied deforming force. A thermoplastic that does not deform in response to an applied deforming force until the thermoplastic is heated to a softening point is another example of active deformation.

Further, as used herein and in the appended claims, the term “contact lithography” generally refers to any lithographic methodology that employs a direct or physical contact between a patterning tool or means for providing a pattern and a substrate or means for receiving the pattern, including a substrate having a pattern receiving layer thereon. Specifically, ‘contact lithography’ as used herein includes, but is not limited to, any form of photographic contact lithography, X-ray contact lithography, and imprint lithography.

As mentioned above, and by way of example, in photographic contact lithography, a physical contact is established between a patterning tool, in this case called a photomask, and a photosensitive resist layer on the substrate (i.e., the pattern receiving means). During the physical contact, visible light, ultraviolet (UV) light, or another form of radiation passing through selected portions of the photomask exposes the photosensitive resist or photoresist layer on the substrate. The photoresist layer is then developed to remove portions that don't correspond to the pattern. As a result, the pattern of the photomask is transferred to the substrate.

In imprint lithography, the patterning tool is a mold that transfers a pattern to the substrate through an imprinting process. In some embodiments, physical contact between the mold and a layer of formable or imprintable material on the substrate transfers the pattern to the substrate. Imprint lithography, as well as a variety of applicable imprinting materials, are described in U.S. Pat. No. 6,294,450 to Chen et al. and U.S. Pat. No. 6,482,742 B1 to Chou, both of which are incorporated herein by reference in their respective entireties.

For simplicity in the following discussion, no distinction is made between the substrate and any layer or structure on the substrate (e.g., a photoresist layer or imprintable material layer) unless such a distinction is helpful to the explanation. Consequently, reference herein is generally to the “substrate” irrespective of whether a resist layer or an imprintable material layer is or is not employed on the substrate to receive the pattern. One of ordinary skill in the art will appreciate that a resist or imprintable material layer may always be employed on the substrate of any contact lithography methodology according to the principles being described herein.

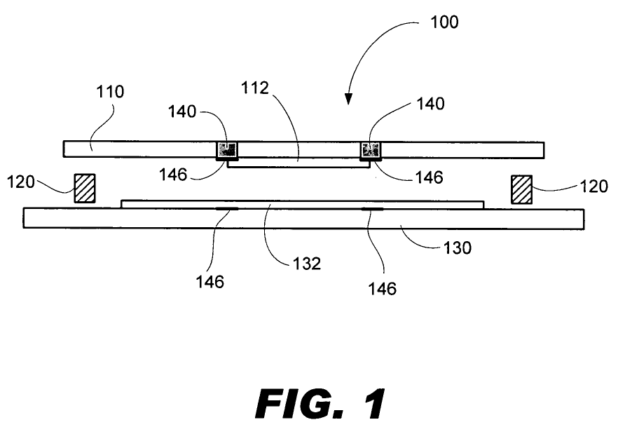

FIG. 1 illustrates a side view of a contact lithography apparatus (100) according to one exemplary embodiment. The contact lithography apparatus (100) comprises a patterning tool (110), which may be for example a mold, mask or other patterning tool, and one or more spacers (120). The contact lithography apparatus (100) imprints or otherwise transfers a pattern from the patterning tool (110) to a substrate (130). In particular, contact between the patterning tool (110) and the substrate (130) is employed during pattern transfer. A patterned area (112) of the patterning tool (110) is brought into contact with a target portion (132) of the substrate (130) and the desired pattern is transferred from the patterning tool (110) to the target portion (132).

As used herein, ‘target portion’ or ‘target area’ refers to that portion of the substrate (110) that receives a copy of a patterning tool pattern as represented by the patterned area (112) of the patterning tool (110). The target portion (132) may include a pattern receiving layer such as a photoresist layer or layer of plastically deformable material specifically configured to receive the pattern of the patterning tool (110). In some cases, the target portion (132) may be heated or otherwise prepared to receive the transferring pattern.

In some examples of a contact lithography apparatus (100), spacers (120) are located between the patterning tool (110) and the substrate (130) prior to and during pattern transfer. The spacers (120) provide for and maintain an essentially parallel and proximal separation between the patterning tool (110) and the substrate (130). In order for the patterning tool (110) to contact the substrate (130) despite the presence of the spacers (120), one or more of the several elements must deform to allow the desired contact. Consequently, deformation of one or more of the patterning tool (110), the spacers (120), and the substrate (130) allows the patterning tool (110) to contact the substrate (130) and permits the transfer of the pattern from the tool (110) to the substrate (130). For example, in some embodiments, one or both of a flexible patterning tool (110) and a flexible substrate (130) are employed. In other embodiments, deformable (e.g., collapsible) spacers (120) are employed. In yet other embodiments, a combination of a flexible patterning tool (110), a flexible substrate and/or deformable spacers (120) are employed. In some embodiments, rigidity may be provided by a plate or carrier that supports one or both of the patterning tool (110) and substrate (130) during pattern transfer. Pattern transfer occurs while the patterning tool (110) and the substrate (130) are in direct contact as a result of the flexure and/or deformation of elements of the system.

In some embodiments, especially where flexure of one or both of the patterning tool (110) and the substrate (130) is employed, the contact between the tool (110) and substrate (130) may occur between the spacers (120) or in a region encompassed or bounded by the spacers (120). For example, the spacers (120) may be located at a periphery of a patterned region of the patterning tool (and/or an area to be patterned of the substrate) and the flexure of the patterning tool (110) and/or the substrate (130) occurs within that periphery.

The spacers (120) illustrated in FIG. 1 are outside of the patterned area (112) of the patterning tool (110). Similarly, the spacers (120) are located outside of the target portion (132) of the substrate (130) as well as outside the patterned area (112) of the patterning tool (110).

In some embodiments, for example, when a deformable spacer or spacers (120) are employed, an essentially non-deformable patterning tool (110) and/or an essentially non-deformable substrate (130) may be used. For example, a semi-rigid or rigid patterning tool (110) that is not deformed or not intended to be deformed during pattern transfer may be used as the patterning tool (110). Furthermore, when using the deformable spacer or spacers (120), one or more of the spacers (120) may be located within a broader patterned area or region. For example, the substrate (130) may be a wafer having a plurality of individual dies or chips defined thereon. The dies have respective local patterned areas. In this example, deformable spacers (120) may be located in spaces or regions between the local patterned areas of the wafer substrate (130). Spaces or regions between local patterned areas include, but are not limited to, ‘streets’ or ‘saw kerfs’ separating the individual dies on the wafer substrate (130).

In some embodiments, the spacer or spacers (120) are components separate from either the patterning tool (110) or the substrate (130). In such embodiments, the spacers (120) are generally positioned, placed, or otherwise inserted between the patterning tool (110) and the substrate (130) prior to establishing contact between the patterning tool (110) and substrate (130) for the pattern transfer.

In other embodiments, the spacers (120) are formed as an integral part of one or both of the patterning tool (110) and the substrate (130). For example, the spacers (120) may be fabricated as extensions of, or an integral part of, the patterning tool (110) in some embodiments. In other embodiments, the spacers (120) may be fabricated as extensions of, or an integral part of, the substrate (130). In yet other embodiments, some of the spacers (120) may be formed as an integral part of one or both of the patterning tool (110) and the substrate (130) while others of the spacers (120) are not integral to either the patterning tool (110) or the substrate (130).

In some embodiments, the spacers (120) that are integral to either the patterning tool (110) or the substrate (130) are formed by depositing or growing a material layer on a respective surface of either the patterning tool (110) or the substrate (130). For example, a silicon dioxide (SiO₂) layer may be either grown or deposited on a surface of a silicon (Si) substrate (130). Selective etching of the deposited or grown SiO₂ layer may be employed to define the spacers (120), for example, resembling stand-off posts. In some embodiments, a uniform height of each of the stand-off post spacers (120) is established by virtue of a simultaneous growth or deposition of the spacers (120). For example, forming the spacers (120) simultaneously using an evaporative material deposition on the substrate (130) surface will generally result in the spacers (120) having essentially identical heights. Alternatively or additionally, post-processing of the grown and/or deposited spacers (120) such as, but not limited to, micro-machining (e.g., chemical-mechanical polishing, etc.) may be employed to further adjust spacer height to achieve uniform height among the spacers. Similar methods may be employed to form the spacers (120) on or as an integral part of the patterning tool (110).

In yet other embodiments, the spacers (120) may be separately fabricated and then affixed to one or both of the patterning tool (110) and the substrate (130) using glue, epoxy or other suitable means for joining. However, whether fabricated as an integral part of, or affixed to, one or both of the patterning tool (110) or the substrate (130), the spacers (120) are so fabricated or affixed prior to performing contact lithography.

In some embodiments, the deformable spacer (120) may exhibit one or both of plastic deformation and elastic deformation. For example, in a plastic deformation of the deformable spacer (120), a deforming force may essentially crush or smash the spacer (120). After being crushed or smashed, little or no significant recovery of an original shape of the spacer (120) will result when the deforming force is removed. In another example, the deformable spacer (120) may undergo an elastic deformation in response to the deforming force. During elastic deformation, the spacer (120) may bend or collapse but the spacer (120) will essentially return to its original shape once the force is removed. An elastically deforming spacer (120) may comprise a rubber-like material or spring-like material/structure, for example.

In various embodiments, the deformable spacer (120) provides one or both of passive deformation and active deformation. A passively deformable spacer (120) may exhibit one or both of plastic and elastic deformation. Materials having a spring-like behavior suitable for use as passively deformable spacers (120) that exhibit elastic deformation include various elastomeric materials. In particular, the spacers (120) may comprise an elastomeric material such as, but not limited to, nitrile or natural rubber, silicone rubber, perfluoroelastomer, fluoroelastomer (e.g., fluorosilicone rubber), butyl rubber (e.g., isobutylene or isoprene rubber), chloroprene rubber (e.g., neoprene), ethylene-propylene-diene rubber, polyester, and polystyrene. Non-elastomeric materials that are formed in a manner that facilitates spring-like behavior during passive deformation may be employed as well. Examples of non-elastomeric materials that can be formed into springs for use as the spacers (120) include metals such as, but not limited to, beryllium copper and stainless steel as well as essentially any relatively rigid polymer. In addition, many conventional semiconductor materials may be micro-machined into mechanical spring configurations. Examples of such materials include, but are not limited to, silicon (Si), silicon oxide (SiO₂), silicon nitride (Si₃N₄), silicon carbide (SiC), gallium arsenide (GaAs), and most other conventional semiconductor materials. Such non-elastomeric materials formed as springs may be used to produce passively deformable spacers (120) that exhibit one or both of plastic and elastic deformation depending on the specific shapes and forces employed.

In various embodiments, one or both of the patterning tool (110) and the substrate (130) may be deformable. The deformable patterning tool (110) and/or the deformable substrate (130) may exhibit one or both of plastic or elastic deformation. Furthermore, the deformable patterning tool (110) and/or substrate (130) may provide one or both of passive or active deformation. In some embodiments, one or both of the patterning tool (110) and substrate (130) may comprise materials described above with respect to the spacer (120) to achieve one or more of elastic, plastic, passive and active deformation.

A process and apparatus for contact lithography is further described in co-pending application Ser. No. 11/203,551 entitled “Contact Lithography Apparatus, System, and Methods” which is incorporated herein by reference in its entirety.

FIG. 1 further illustrates alignment tools integrated with the patterning tool (110). In the illustrated example, the patterning tool (110) includes at least one integrated alignment device (140) for measuring alignment between the patterning tool (110) and the substrate (130). More specifically, the alignment device (140) measures alignment between a patterned area (112) of the patterning tool (110) and a target area (132) of the substrate (130). The alignment device (140) may extend completely through the patterning tool (110), partially through the patterning tool (110), be bonded to at least one side of the patterning tool (110), or be otherwise coupled to the patterning tool (110).

According to the exemplary embodiment of FIG. 1, the alignment device (140) is configured to measure and detect lateral and rotational alignment. In additional embodiments, the alignment device and/or one or more additional alignment devices (140) may be configured to measure tilt, separation distance, or other conditions or relationships between the patterning tool (110) and/or substrate (130). Alignment devices (140) may alternately or additionally be integrated into at least one substrate (130) or spacer (120).

The patterning tool (110), the substrate (130), the target area (132), and even the alignment device (140) itself may include an alignment pattern (146) to facilitate alignment. In some exemplary embodiments, at least one alignment device (140) includes an alignment pattern (146) and a substrate (130) also includes a corresponding alignment pattern (146). The alignment patterns (146) on the alignment device (140) and substrate (130) may be identical or substantially similar, but are not required to be identical or substantially similar. During the alignment process, the features of the alignment patterns (146) on a substrate (130) may be correlated with features of the alignment patterns (146) on one or more alignment devices (140). Once the features of the alignment patterns (146) have been correlated, the relationships may indicate the accuracy of alignment and may indicate potential adjustments to improve alignment. Multiple alignment patterns (146) may be included on a patterning tool (110), alignment device (140), substrate (130), and/or target area (132) and may be located at edges, corners, surfaces, or any other measurable area. In an embodiment employing an optical sensor or sensor array, for example, the alignment patterns (146) may be placed so that light reflected from the alignment patterns may be received by the sensor.

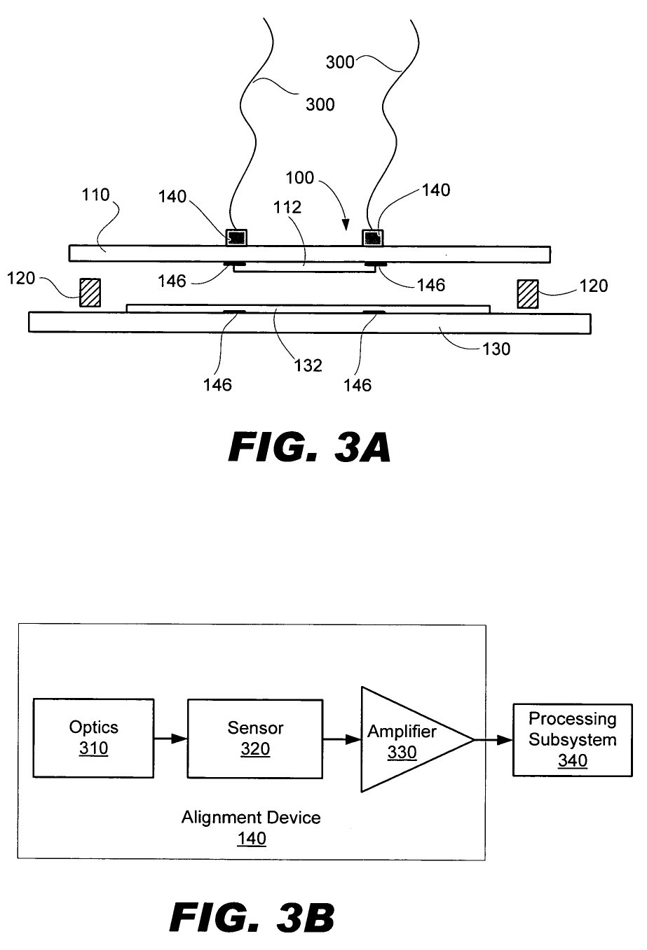

Light, images, electrical signals, or data representative of detected light may be transmitted from an alignment device (140) in a patterning tool (110) to a processing subsystem (340, FIG. 3B) external to the alignment device (140). Since the subsystem (340) for processing the light or data may be physically distinct from the alignment device (140) capturing the light or data, vibrations affecting the processing subsystem (340) will not degrade the quality of alignment data.

The alignment device (140) may be positioned at any of a variety of locations on the patterning tool (110). For example, in some embodiments, an alignment device (140) is coupled to the side of the patterning tool (110) opposite the patterned area (112). A transparent section of the patterning tool (110) may then allow light to pass through the patterning tool (110) enabling the alignment device (140) to measure alignment of the patterning tool (110) relative to the substrate (130).

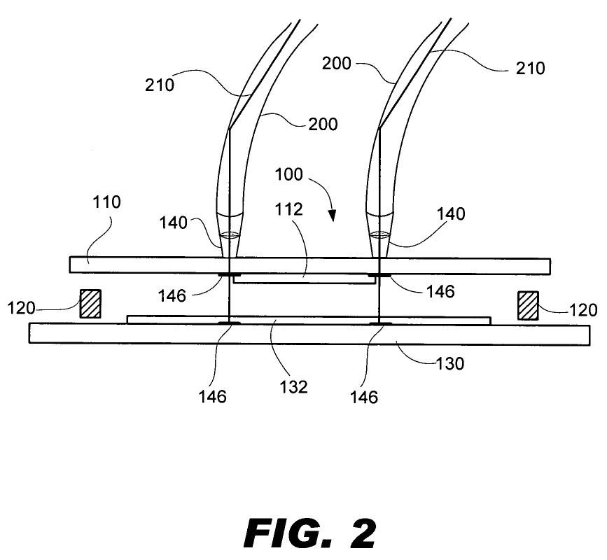

In some embodiments, at least one alignment device (140) is an optical device. An optical alignment device (140) may include, but is not limited to, a lens, mirror, optical fiber, filter, light source, waveguide, or other device for manipulating, generating, or transmitting light. As illustrated in FIG. 2, an alignment device (140) may include multiple optical devices, such as lenses and filters, and may transmit an image from a patterning tool (110) through an optical fiber (200). The light (210) received through the optical fiber may then be analyzed to measure the accuracy of alignment between a patterning tool (110) and a substrate (130). In the embodiment of FIG. 2, light may be transmitted to the alignment device (140) by an external device or through the optical fiber (200) or light may be generated by the alignment device (140), for example, such as with a light emitting diode (LED).

In other embodiments, the alignment device (140) includes an optical sensor in addition to, or instead of, other optical devices. An optical sensor may include, but is not limited to, a charge coupled device (CCD), complementary metal-oxide semiconductor (CMOS) image sensor, phototransistor, photoresistor, photodiode, or other light sensing device. According to the exemplary embodiment of FIG. 3A, optical sensors are incorporated into the alignment devices (140) and electrical signals representative of images or alignment measurements are transmitted through wires (300). An optical sensor may include additional devices, members, or circuitry to enable the sensor to communicate with other alignment devices or improve output, such as an analog to digital converter (ADC), amplifier, memory device, or processor.

FIG. 3B illustrates various components that may be incorporated into an alignment device (140) and a connection to an external processing subsystem (340). Optics (310) focus, direct, or filter light to enable the sensor (320) to measure at least one relationship or condition of interest. In the embodiment of FIG. 3B, the sensor (320) represents the information of interest as an electrical signal. The signal is amplified with an amplifier (330) and sent to a processing subsystem (340) which is not coupled to the patterning tool (110).

The processing subsystem (340) receives alignment data in the form of light (See the example of FIG. 2), electrical signals (See the example of FIG. 3A), or other means. The processing subsystem (340) may then compare the data received to expected or desired measurements to determine the current status of alignment. After interpreting the received data, the processing subsystem (340) may then determine adjustments to improve alignment and transmit them to other components of the alignment system. As alignment adjustments are made, the alignment devices (140) and processing subsystem (340) may provide accurate and timely feedback to control the alignment process.

The elements illustrated in FIG. 3B are intended to be only exemplary. Many embodiments may omit components or include additional components.

Additional non-optical devices and sensors may be incorporated into an alignment device (140) to measure alignment and facilitate alignment adjustment, including micro electro-mechanical systems (MEMS), mechanical devices, capacitive sensors, pressure sensors, or other devices.

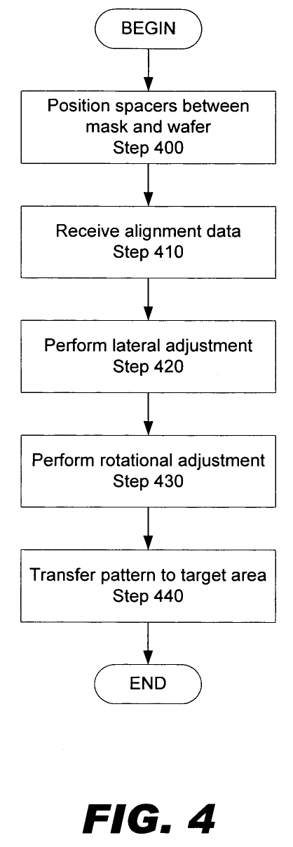

FIG. 4 is a flowchart illustrating a method for aligning a patterning tool and substrate in a contact lithography system, according to at least one exemplary embodiment.

First, spacers are placed between the patterning tool and substrate (step 400). As described above, the spacers may be separate from or integral with either the patterning tool, the substrate or both. Because the spacers are in contact with the patterning tool and substrate, any vibrations in the system will tend to displace the patterning tool, spacer, and substrate as a single unit. The use of spacers ensures that the patterning tool and substrate are maintained in the same relative positions, i.e., parallel and proximal to each other, unless adjustments to the alignment are being made. Additionally, coarse alignment between a patterning tool and substrate may be performed along with the placement of spacers. This step may include orienting a patterning tool and substrate substantially parallel and proximal to each other with initial lateral and/or rotational alignment. Step 400 may use alignment indicators and mechanisms other than the alignment patterns (146) and alignment devices (140) of FIGS. 1-3. In one embodiment, coarse alignment may facilitate the accurate positioning of spacers between a patterning tool and a substrate to be patterned.

Once the patterning tool, substrate, and spacers are placed, alignment data is received from at least one alignment device coupled to the patterning tool (step 410). As described above, this data may be transmitted in a variety of forms and may be processed and utilized by one or more subsystems.

Next, lateral adjustment (step 420) and rotational adjustment (step 430) are performed. Steps 42Q and 430 can be performed sequentially, simultaneously, or in reversed order and may be performed repeatedly for incremental alignment adjustments. Alignment adjustments may be made by moving the substrate or patterning tool or both. According to one exemplary embodiment, the alignment data received during step 410 may be used to determine the type and degree of lateral and rotational adjustments made during steps 420 and 430.

Steps 410 through 430 may be repeated a set number of times or until a condition or misalignment tolerance is reached. Alignment data received may serve as feedback data to control the alignment process. Also, step 410 may be performed concurrently with steps 420 and 430, which may reduce the time required for alignment or increase the precision and accuracy of the alignment process.

After alignment has reached an acceptable tolerance, at least one pattern is transferred from the patterning tool to the substrate (step 440). In imprint lithography, contact of the patterned area with the target area forms the pattern on the substrate. According to one exemplary embodiment, the pattern transfer step includes heating, cooling, applying pressure, or otherwise manipulating a substrate to receive a pattern. In contact photolithography, pattern transfer (step 450) may include exposure to light or other radiation for a period of time to develop a pattern on the target area.

The above steps may then be repeated for another substrate or for a different target area of the same substrate. Additionally, subsequent layers of the same target area may be patterned with additional patterning tools using the above process, although additional steps may be performed before the above process is repeated.

The preceding description has been presented only to illustrate and describe examples of the principles discovered by the applicants. This description is not intended to be exhaustive or to limit these principles to any precise form or example disclosed. Many modifications and variations are possible in light of the above teaching.

What is claimed is:

1. A contact lithography system comprising:
a patterning tool having a pattern for transfer to a substrate; and
at least one alignment device coupled to said patterning tool,
wherein said alignment device is configured to measure alignment between said patterning tool and a substrate for receiving said pattern of said patterning tool.

2. The system of claim 1, comprising at least one spacer disposed between the patterning tool and a substrate being patterned.

3. The system of claim 1, wherein said spacer is integrated with said patterning tool.

4. The system of claim 1, further comprising at least one alignment pattern integrated into said patterning tool.

5. The apparatus of claim 4, wherein said alignment pattern is integrated into said alignment device of said patterning tool.

6. The system of claim 4, wherein a substrate to be patterned comprises at least one alignment pattern.

7. The system of claim 1, wherein said alignment device optically measures said alignment.

8. The system of claim 1, wherein said alignment device is communicatively coupled to a processing subsystem separate from said patterning tool and substrate.

9. The system of claim 8, wherein said alignment device transmits alignment data as electrical data signals to said processing subsystem.

10. The system of claim 8, wherein said alignment device transmits images along fiber optical cable to said processing subsystem.

11. The system of claim 1, wherein said alignment device includes a charge coupled device.

12. The system of claim 1, wherein said alignment device includes a complementary metal-oxide semiconductor sensor.

13. The system of claim 1, wherein said alignment device includes a light source.

14. The system of claim 1, wherein said alignment device is positioned on an opposite side of said patterning tool from said substrate, said patterning tool comprising a transparent potion through which said alignment device determines alignment with said substrate.

15. A contact lithography method comprising aligning a patterning tool having a pattern for transfer with a substrate for receiving said pattern of said patterning tool using at least one alignment device coupled to said patterning tool.

16. The method of claim 15, further comprising mechanically coupling said patterning tool and said substrate with at least one spacer disposed between the patterning tool and substrate.

17. The method of claim 15, further comprising comparing an alignment pattern of said patterning tool with an alignment pattern of said substrate using said alignment device to determined alignment.

18. The method of claim 17, further comprising transmitting alignment data as electrical data signals from said alignment device to a processing subsystem.

19. The method of claim 17, further comprising transmitting images of said alignment patterns over fiber optical cable from said alignment device to a processing subsystem.

20. A contact lithography apparatus comprising:
means for providing a pattern;
means for receiving the pattern;
means for measuring at least one relationship between said means for providing a pattern and said means for receiving the pattern, wherein said means for measuring is integrated with said means for providing a pattern.

21. The system of claim 20, further comprising means for adjusting at least one positional relationship between said means for providing a pattern and said means for receiving the pattern.
